(19) United States
(12) Patent Application Publication
(10) Pub. No.: US 2025/0311441 A1
(43) Pub. Date: Oct. 2, 2025

(54) ELECTROSTATIC DISCHARGE PROTECTION CIRCUIT USING GAN-BASED DEVICES

(71) Applicant: UNITED MICROELECTRONICS CORP., Hsin-Chu City (TW)

(72) Inventors: Yu-Hsuan Chang, New Taipei City (TW); Ching-Wei LI, Hsinchu City (TW); Jih-San Lee, Hsinchu City (TW); Tien-Hao Tang, Hsinchu City (TW)

(73) Assignee: UNITED MICROELECTRONICS CORP., Hsin-Chu City (TW)

(21) Appl. No.: 18/657,740

(22) Filed: May 7, 2024

(30) Foreign Application Priority Data
Mar. 27, 2024 (TW) 113111408

(51) Int. Cl. H01L 27/02; H01L 27/06; H01L 29/20; H01L 29/778

(52) U.S. Cl. CPC H10D 89/60; H10D 30/475; H10D 62/8503; H10D 84/811

(57) ABSTRACT

An ESD protection circuit using GaN devices, with a ESD block including a first 2 DEG resistor with one terminal coupled to a gate of a power HEMT, a first trigger with one terminal coupled to another terminal of the first 2 DEG resistor and with another terminal coupled to a reference voltage, a first LV-HEMT with a first gate coupled to the another terminal of the first 2 DEG resistor and a first drain couple to the gate, a second trigger with one terminal coupled to the gate, a second 2 DEG resistor with one terminal coupled to another terminal of the second trigger and another terminal coupled to the reference voltage, and a second LV-HEMT with a second gate coupled to the another terminal of the second trigger and a second drain coupled to the first source and a second source coupled to the reference voltage.

### BACKGROUND OF THE INVENTION

### 1. Field of the Invention

The present invention relates generally to an electrostatic discharge (ESD) protection circuit, and more specifically, to an ESD protection circuit using GaN devices.

### 2. Description of the Prior Art

Most of semiconductor devices currently available in the world are silicon-based semiconductor using silicon as their basic materials and channel. However, in the application of high-voltage or high-power devices, silicon-based devices may suffer high power consumption since their on-state resistance is too large. Furthermore, in high-frequency operation, silicon-based device has relatively lower switch frequency, thus its performance is no match for wide band gap compound semiconductor material like gallium nitride (GaN) or silicon carbide (SiC). In comparison to conventional silicon-based material, wide band gap compound semiconductor material like GaN is provided with larger band gap and lower on-state resistance, thus it is more durable and applicable in high temperature, high voltage, high frequency and high current applications, and also has better energy conversion efficiency. Thus, GaN device is provided with all kinds of excellent properties required in semiconductor device, like good heat dissipation, small size, lower power consumption and high power, which is suitable for the application of power semiconductor devices. With the urgent demand in high-end industry like 5G communication and electric car, GaN material emerges to be a promising candidate of the third generation semiconductor materials in the future.

Nevertheless, GaN device is usually provided with smaller gate-to-source breakdown voltage (ex. less than 10V), and this makes the gate of GaN device susceptible to gate voltage overshoot and causes damage. Electrostatic discharge (ESD) is one type of voltage overshoot, resulting from sudden release of electrostatic charges, inducing high intense electric field and current in ICs, thereby damaging the GaN devices in the circuit, especially the power GaN device that bears the brunt of the ESD. Accordingly, those of skilled in the art needs to design and develop a kind of circuit and structure capable of protecting GaN devices, especially against the weakness of smaller gate-to-source breakdown voltage, in hope of providing better application of GaN devices.

### SUMMARY OF THE INVENTION

In the light of the aforementioned weakness of GaN device susceptible to the damage of voltage overshoot, the present invention hereby provides a novel ESD protection circuit, with feature that components in the ESD protection circuit may all be GaN-based devices, including resistor, capacitor, diode or high electron mobility transistor (HEMT), so that those devices may be made on the same GaN substrate and integrated in the same process.

The objective of the present invention is to provide an ESD protection circuit using GaN devices, with structure including a power HEMT having a gate, a source and a drain, the source and drain are coupled respectively to a first reference voltage and a second reference voltage. An ESD block includes a first sub-block, the first sub-block includes: a first 2 DEG resistor with one terminal coupled to the gate, a first trigger with one terminal coupled to another terminal of the first 2 DEG resistor and with another terminal coupled to the first reference voltage, and a first LV-HEMT has a first gate, a first source and a first drain, the first gate is coupled to the another terminal of the first 2 DEG resistor and the terminal of the first trigger, and the first drain is coupled to the gate. The ESD protection further includes a second sub-block. The second sub-block includes a second trigger with one terminal coupled to the gate; a second 2 DEG resistor with one terminal coupled to another terminal of the second trigger and with another terminal coupled to the first reference voltage; and a second LV-HEMT with a second gate, a second source and a second drain, the second gate is coupled to the another terminal of the second trigger and the terminal of the second 2 DEG resistor, and the second drain is coupled to the first source of the first LV-HEMT, and the second source is coupled to the first reference voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic diagram of an ESD protection circuit using GaN-based devices in accordance with one embodiment of the present invention;

FIG. 2 is a schematic diagram of an ESD protection circuit using GaN-based devices in accordance with another embodiment of the present invention;

FIG. 3 is a schematic cross-section of a GaN-based capacitor in accordance with one embodiment of the present invention;

FIG. 4 is a schematic cross-section of a MIM capacitor in accordance with one embodiment of the present invention;

FIG. 5 is a schematic cross-section of a GaN-based resistor in accordance with one embodiment of the present invention;

FIG. 6 is a schematic cross-section of a GaN-based lateral field effect rectifier (LFER) in accordance with one embodiment of the present invention; and

FIG. 7 is a schematic cross-section of a LV-HEMT in accordance with one embodiment of the present invention.

Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “substrate” refers to a material onto which subsequent material layers are added. The substrate itself can be patterned, and the materials added on top of the substrate can be patterned or remain unpatterned. The substrate in the specification is specified as GaN-based substrate, with semiconductor device manufactured thereon being specified generally as GaN-based device.

As used herein, the term “layer” refers to a material portion including a region with thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The subject of present invention is to provide an electrostatic discharge (ESD) protection circuit based on GaN-based devices. In comparison to conventional Si-based MOSFET, GaN-based high electron mobility transistor (HEMT) has lower threshold voltage and smaller gate-to-source on-state resistance. In one aspect, these properties render the HEMT with lower necessary gate driving force and higher current and switching frequency. In another aspect, lower gate breakdown voltage of HEMT may also induce the damage of gate terminal, since voltage surge of gate overshoot may easily exceed the gate breakdown voltage. Accordingly, in actual implementation, gate protection circuit is usually adopted in industry to protect GaN-based HEMTs in order to avoid device damage caused by the generated voltage surge during device switching or electrostatic discharging. In the embodiment of present invention, the referred HEMT devices are all considered as enhancement mode E-HEMTs with normally-off property, unless otherwise stated.

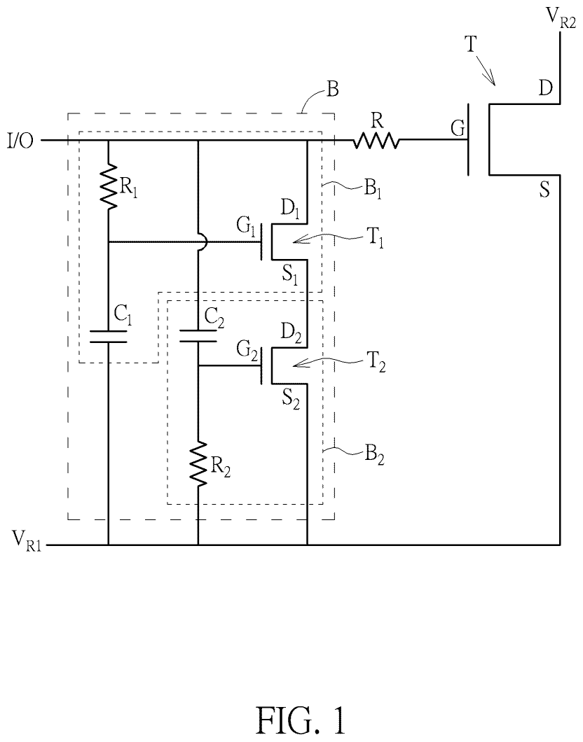

First, please refer to FIG. 1, which is a schematic diagram of an ESD protection circuit using GaN-based devices in accordance with one embodiment of the present invention, illustrating various GaN-based devices that constitute the ESD protection circuit of the present invention. As shown in FIG. 1, the ESD protection circuit of present invention includes a power E-HEMT T, which may be used to amplify power in amplifying circuit, suitable in the field of radio frequency, microwave or mmWave, etc. Since the power E-HEMT T is GaN-based transistor, its gate terminal is susceptible to the damage due to the surge of voltage overshoot. As shown in FIG. 1, the power E-HEMT T includes a gate G, a source S and a drain D, wherein the source S and drain D are coupled respectively to a first reference voltage V_{R1} (ex. ground voltage V_{SS}) and a second reference voltage V_{R2} (ex. operating voltage V_{DD}). In order to protect the gate G of power E-HEMT T, an ESD protection block B is designed in the circuit to couple between the gate G and source S of the power E-HEMT T to provide ESD protection function. In normal operating voltage condition, ESD block B is inactive and the power E-HEMT T operates in normal mode. However, voltage overshoot may be generated during device switching or ESD, the ESD protection block B is designedly active at this time to protect power E-HEMT T from the impact of voltage surge and avoid gate damage. In the embodiment, the gate G of power E-HEMT T may be coupled directly to an input/output terminal I/O of a IC chip through the ESD block B, and a resistor R (ex. a two-dimensional electron gas (2 DEG) resistor, referred hereinafter as a main resistor) may be set designedly between the ESD block B and gate G to further lower the voltage applied on the gate G. One or more other circuit may be further set between the ESD block B and I/O terminal, but not limited thereto.

Refer still to FIG. 1. The ESD block B is divided into a first sub-block B₁ and a second sub-block B₂ with different trigger voltages respectively. In the embodiment of present invention, the first sub-block B₁ and second sub-block B₂ are both coupled between the gate G and source S of the power E-HEMT T, but in inverted configuration. More specifically, the first sub-block B₁ is composed of a first 2 DEG resistor R₁, a first capacitor C₁ and a first low-voltage HEMT (LV-HEMT) T₁, wherein the first 2 DEG resistor R₁ functions as a voltage divider, with one terminal coupled to the gate of power HEMT T (may pass through main resistor R) and I/O terminal. The first capacitor C₁ functions as one of triggers in ESD protection circuit, with one terminal coupled to another terminal of the first 2 DEG resistor R₁ and with another terminal coupled to first reference voltage V_{R1} and the source S of power HEMT T. The first LV-HEMT T₁ is designedly as a switching device in discharging path, with a specific threshold voltage. The first LV-HEMT T₁ further includes a first gate G₁, a first source S₁ and a first drain D₁, wherein the first gate G₁ is coupled to the another terminal of first 2 DEG resistor R₁ and one terminal of the first capacitor C₁, and the first drain D₁ is coupled to the gate G of power HEMT T (may pass through main resistor R) and I/O terminal. In operation, when the voltage of first source S₁ or first drain D₁ is greater than the voltage of first gate G₁ and the voltage difference therebetween exceeds the threshold voltage of first LV-HEMT T₁, the first LV-HEMT T₁ is conducted.

Refer still to FIG. 1. The structure of second sub-block B₂ is similar to the one of first sub-block B₁, but in an inverted circuit configuration. As shown in FIG. 1, the second sub-block B₂ is composed of one second 2 DEG resistor R₂, one second capacitor C₂ and one second LV-HEMT T₂, wherein the second 2 DEG resistor R₂ functions as a voltage divider, with one terminal coupled to the source S of power HEMT T and first reference voltage V_{R1}. The second capacitor C₂ functions as another trigger in the ESD protection circuit, with one terminal coupled to another terminal of the second 2 DEG resistor R₂ and with another terminal coupled to the gate G of power HEMT T (may pass through main resistor R) and I/O terminal. The second LV-HEMT T₂ is designedly as a switching device in discharging path, which is provided with a specific threshold voltage. The second LV-HEMT T₂ further includes a second gate G₂, a second source S₂ and a second drain D₂, wherein the second gate G₂ is coupled to the another terminal of second 2 DEG resistor R₂ and the terminal of the second capacitor C₂, the second drain D₂ is coupled to the first source S₁ of first LV-HEMT T₁, and the second source S₂ is coupled to the source S of power HEMT T and the first reference voltage. In operation, when the voltage of second source S₂ or second drain D₂ is greater than the voltage of second gate G₂ and the voltage difference therebetween exceeds the threshold voltage of second LV-HEMT T₂, the second LV-HEMT T₂ is conducted.

In actual operation, when the positive voltage surge resulted from ESD enters the chip from I/O terminal, the voltage of another terminal of second capacitor C₂ and first gate G₁ of the first LV-HEMT will be asserted upward to an active level. Since the threshold voltage of first LV-HEMT T₁ is designedly less than the threshold of second capacitor C₂, the ESD surge will firstly turn on the first LV-HEMT T₁. However, the mere turning-on of first LV-HEMT T₁ does not result in a complete conduction path from I/O terminal to first reference voltage V_{R1}, thus no current passes through the first LV-HEMT T₁ at this moment. The second capacitor C₂ also remains un-conducted until the voltage of the another terminal of second capacitor C₂ is asserted upward to the active level and with the voltage difference therebetween exceed the threshold voltage of second capacitor C₂, then the second capacitor C₂ is conducted.

Furthermore, after the second capacitor C₂ is conducted, a first conduction path from I/O terminal to first reference voltage V_{R1} through the second capacitor C₂ and the second 2 DEG resistor R₂ is formed. Since the second 2 DEG resistor R₂ has larger resistance designedly, the current passing through the first conduction path would be smaller. With the voltage asserting of second capacitor C₂, the voltage of the terminal of second capacitor C₂ is also increased, until the voltage difference of the second gate G₂ of second LV-HEMT T₂ exceeds the threshold voltage of second LV-HEMT T₂, then the second LV-HEMT T₂ is conducted.

Following previous operation, since the first LV-HEMT T₁ is already conducted before, a second conduction path from I/O terminal to the first reference voltage V_{R1} through the first LV-HEMT T₁ and second LV-HEMT T₂ is formed when the second LV-HEMT T₂ is conducted. In the embodiment of present invention, the first LV-HEMT T₁ and second LV-HEMT T₂ are designedly robust, for example having larger area and able to withstand larger current, thus the second conduction path is in fact a channel for releasing ESD surge. That is the mechanism of ESD protection in the present invention.

Conversely, when a negative voltage surge enters the chip from the I/O terminal, its protection mechanism would be completely opposite to the aforementioned mechanism, with the second LV-HEMT T₂ asserted upward firstly and conducted, then the first capacitor C₁ conducted, and the first LV-HEMT T₁ is active and conducted lastly, so as to establish a second conduction path for releasing ESD surge.

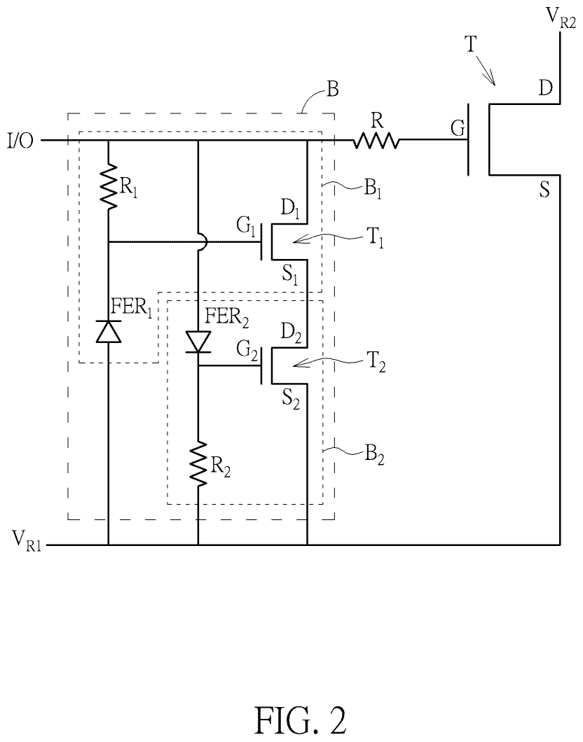

Please refer now to FIG. 2, which is a schematic diagram of an ESD protection circuit using GaN-based devices in accordance with another embodiment of the present invention. The circuit components in this embodiment is much the same as the embodiment of FIG. 1, with the difference only that the two triggers in this embodiment are changed from capacitors C₁/C₂ to lateral field effect rectifiers FER₁/FER₂. In this embodiment, one trigger may include one or more lateral field effect rectifiers in serial connection (represented by only one symbol in the figure). The lateral field effect rectifiers FER₁/FER₂ may achieve the same purpose as the capacitors C₁/C₂ in the protection circuit of present invention, and its operating mechanism is the same as aforementioned embodiment, thus redundant description will be herein omitted.

After the circuit structure of ESD protection circuit of the present invention is explained, following figures and embodiments will describe various GaN-based devices used in the circuit in cross-sectional view. One essential feature of the present invention lies that the components in the circuit may all be GaN-based devices, which may be made on the same GaN substrate and integrated in the same process.

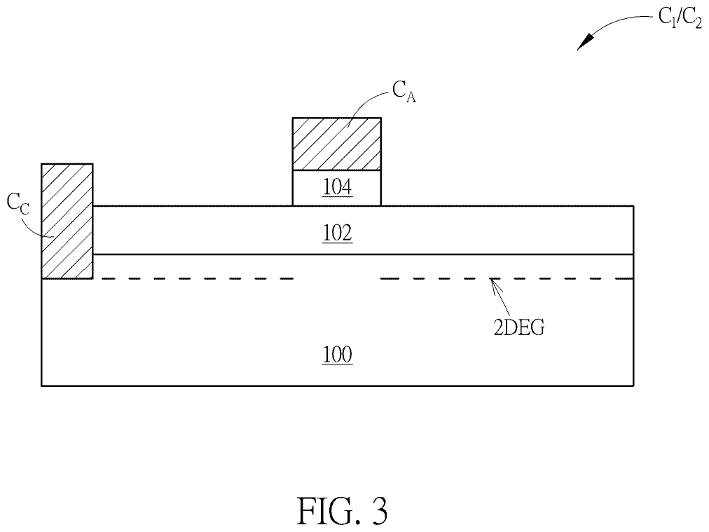

Please refer first to FIG. 3, which is a schematic cross-section of a capacitor in accordance with one embodiment of the present invention, illustrating detailed structure of the first capacitor C₁ or second capacitor C₂ in FIG. 1. As shown in FIG. 3, the capacitors C₁/C₂ of present invention may be GaN-based capacitors, which set on a GaN substrate 100. Alternatively, the GaN substrate 100 may be a GaN epitaxial layer formed on conventional silicon substrate, with layer structure like buffer layers and superlattice layers formed therebetween, but not limited thereto. Following figures will use only one GaN substrate 100 as a representative. In the embodiment, an aluminum gallium nitride (AlGaN) layer 102 is formed on the GaN substrate 100, and a heterojunction having band gap discontinuity is formed between the AlGaN layer 102 and the GaN substrate 100, thus electrons generated from piezoelectric effect in the AlGaN layer 102 will be trapped into the GaN substrate 100, thereby forming a high mobile and conductive electron film adjacent to the interface of two layer structures, i.e. 2 DEG, which may function as a channel for transistor devices. Furthermore, since enhancement mode GaN device with normally-off property is preferred in the present invention, a patterned p-type GaN layer 104 (p-GaN, for example using GaN doped with elements like C, Fe, Mg or Zn) is further formed on the AlGaN layer 102 to deplete the 2 DEG right thereunder to form non-conductive depletion region.

Refer still to FIG. 3. In addition to the conductive region and non-conductive region formed by the GaN material, the first capacitor C₁ or second capacitor C₂ further include an anode C_{A} formed on the p-GaN layer 104 and a cathode C_{C} formed on the GaN substrate 100 and AlGaN layer 102 at one side of the p-GaN layer 104 to function as two electrodes of the capacitor. The material of anode C_{A} and cathode C_{C} may include refractory metal or conductive layer of relevant compound, like Ti, TiN, TiW and W, or may include Ni, Au, Cu or the alloy thereof. In the embodiment of present invention, the anode C_{A} and cathode C_{C} are conductive terminals at two ends of the GaN capacitor, while the non-conductive region therebetween is capacitive dielectric layer, ex. AlGaN layer 102 and p-GaN layer 104. When there is voltage applied between the two conductors insulated by the non-conductive region, electric field will be formed on the non-conductive region, so as to make positive charges concentrating on one conductor and negative charges concentrating on another conductor. For example, take the second capacitor C₂ as an example, when positive voltage surge enters the chip from I/O terminal, the cathode C_{C} is equivalent to the another terminal that is coupled with the I/O terminal, while anode C_{A} is equivalent to the terminal that is coupled with the first reference voltage V_{R1}. The first capacitor C₁ is in inverted configuration in the condition of negative voltage surge. In other embodiment, the positions of cathode C_{C} and anode C_{A} may be interchanged, but not limited thereto. The capacitance produced by this GaN-based capacitor is preferably between 1 pF-50 pF.

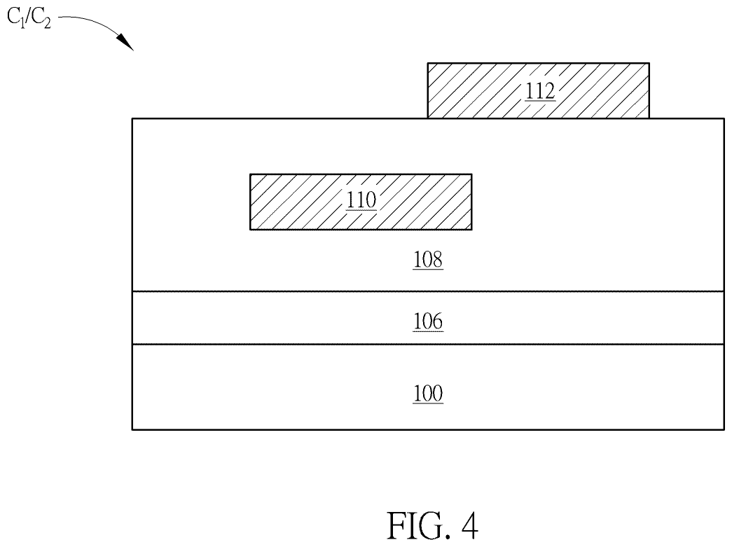

Please refer now to FIG. 4, which is a schematic cross-section of a capacitor in accordance with another embodiment of the present invention. In addition to the aforementioned GaN-based capacitor, the first capacitor C₁ or second capacitor C₂ of present invention may also be common metal-insulator-metal (MIM) capacitor. As shown in FIG. 4, similarly, the first capacitor C₁ or second capacitor C₂ is manufactured on the GaN substrate 100. Different from the previous embodiment that AlGaN layer 102 is formed to generate 2 DEG, instead, an ion implant isolation layer 106 is formed on the GaN substrate 100, for example by heavily doping the surface of GaN substrate 100 to form a non-conductive layer, in order to avoid electrical coupling between the GaN substrate and the conductive layer formed thereon. A passivation layer 108 is formed on the ion implant isolation layer 106, with material like one or more layer of SiO₂, SiN, SiON, USG (undoped silicate glass) or PSG (phosphosilicate glass). In the embodiment, an anode metal layer 110 and a cathode metal layer 112 may be formed respectively in or on the passivation layer 108 to function as two electrodes of the capacitor. The material of anode metal layer 110 and cathode metal layer 112 may include refractory metal or conductive layer of relevant compound, like Ti, TiN, TiW and W, or may include Ni, Au, Cu or the alloy thereof. The passivation layer 108, anode metal layer 110 and cathode metal layer 112 may be integrally formed in semiconductor BEOL (back-end-of-line) process. Similarly, in the embodiment of present invention, the anode metal layer 110 and cathode metal layer 112 are the conductors at two terminals of the MIM capacitor, while the passivation layer 108 therebetween is capacitive dielectric layer. When there is voltage applied between the anode metal layer 110 and the cathode metal layer 112, electric field will be formed in the passivation layer 108, so as to make positive charges concentrating on one conductor and negative charges concentrating on another conductor. For example, take the second capacitor C₂ as an example, when positive voltage surge enters the chip from I/O terminal, the cathode metal layer 112 is equivalent to the another terminal that is coupled with the I/O terminal, while the anode metal layer 110 is equivalent to the terminal that is coupled with the first reference voltage V_{R1}. The first capacitor C₁ is in inverted configuration in the condition of negative voltage surge. In other embodiment, the positions of anode metal layer 110 and cathode metal layer 112 may be interchanged, but not limited thereto. The capacitance produced by this MIM capacitor is preferably between 1 pF-50 pF.

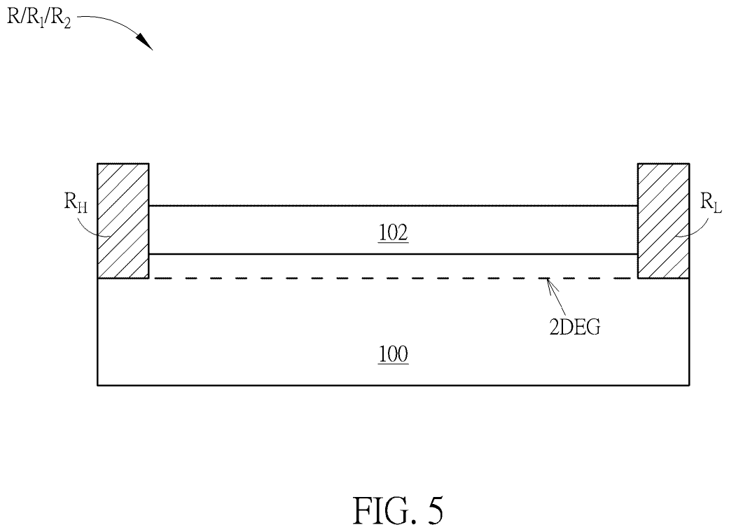

Please refer now to FIG. 5, which is a schematic cross-section of a GaN-based resistor in accordance with one embodiment of the present invention, illustrating detailed structures of the main resistor R, first 2 DEG resistor R₁ and/or second 2 DEG resistor R₂ in FIG. 1. As shown in FIG. 5, likewise, the resistors R/R₁/R₂ of present invention are set on GaN substrate 100. An AlGaN layer 102 is formed on the GaN substrate 100, so as to form a 2 DEG as conductive channel. Different from the previous embodiments, there is no pattern of p-GaN layer 104 formed on the AlGaN layer 102 to produce non-conductive depletion region. In other word, the entire 2 DEG is the main body of resistor. A high-voltage terminal R_{H} and a low-voltage terminal R₁ are formed on the AlGaN layer 102 and GaN substrate 100 respectively at two terminals of the resistor R/R₁/R₂. Take the first 2 DEG resistor R₁ as an example, the high-voltage terminal R_{H} is the terminal coupled with the I/O terminal and the gate G of power HEMT T, while the low-voltage terminal R_{L} is the another terminal coupled with the first capacitor C₁. The resistance produced by this GaN-based resistor is preferably between 50 Ω-100 kΩ.

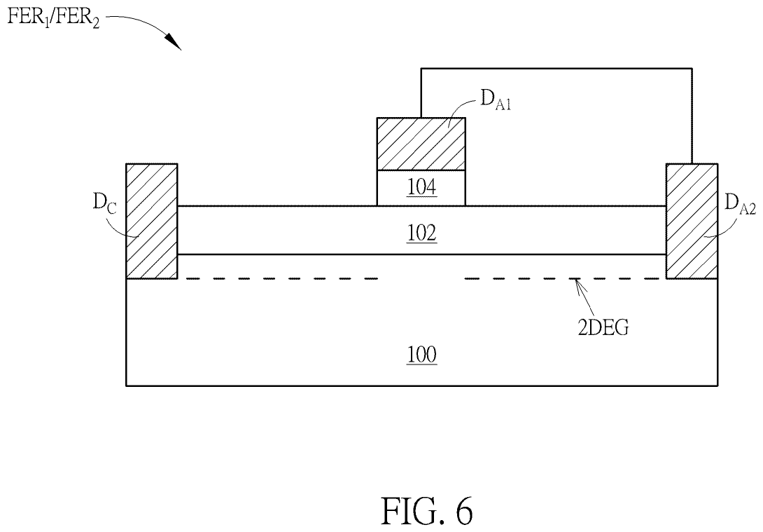

Please refer now to FIG. 6, which is a schematic cross-section of a lateral field effect rectifier functioning as a trigger in accordance with one embodiment of the present invention, illustrating detailed structures of lateral field effect rectifiers FER₁/FER₂ in FIG. 2. As shown in FIG. 6, likewise, the lateral field effect rectifiers FER₁/FER₂ are set on the GaN substrate 100. An AlGaN layer 102 is formed on the GaN substrate 100 so as to form a 2 DEG as conductive channel. A p-GaN layer 104 is further formed on the AlGaN layer 102 to deplete the 2 DEG right thereunder in order to form non-conductive depletion region. Furthermore, the lateral field effect rectifiers FER₁/FER₂ further includes a first anode D_{A1} formed on the p-GaN layer 104, and a second anode D_{A2} and a cathode D_{C} formed on the GaN substrate 100 and AlGaN layer 102 respectively at two sides of the p-GaN layer 104. Specifically, the first anode D_{A1} and second anode D_{A2} are coupled with each other to fulfill the rectifying function like forward conducting and reverse blocking of the diode device with properties like low on-state resistance and high reverse withstand. In the embodiment, the width of first anode D_{A1} (in the direction perpendicular to page) is preferably between 50 μm-1000 μm. Likewise, the material of first anode D_{A1}, second anode D_{A2} and cathode D_{C} may include refractory metal or conductive layer of relevant compound, like Ti, TiN, TiW and W, or may include Ni, Au, Cu or the alloy thereof. In the embodiment of present invention, take the second lateral field effect rectifier FER₂ as an example, when positive voltage surge enters the chip from I/O terminal, cathode C_{C} is equivalent to the another terminal that is coupled with the I/O terminal, while the first anode D_{A1} and second anode D_{A2} are equivalent to the another terminal that is coupled with the first reference voltage V_{R1}. The first lateral field effect rectifier FER₁ is in inverted configuration in the condition of negative voltage surge.

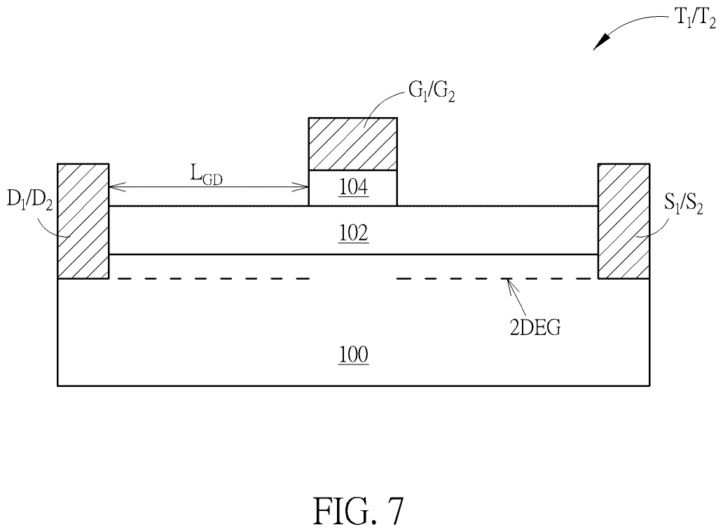

Please refer now to FIG. 7, which is a schematic cross-section of a LV-HEMT in accordance with one embodiment of the present invention, illustrating detailed structures of first LV-HEMT T₁/second LV-HEMT T₂ in FIG. 1. As shown in FIG. 7, likewise, the first LV-HEMT T₁/second LV-HEMT T₂ in the present invention are set on GaN substrate 100. An AlGaN layer 102 is formed on the GaN substrate 100 so as to form a 2 DEG as conductive channel. A pattern of p-GaN layer 104 is further formed on the AlGaN layer 102 to deplete the 2 DEG right thereunder in order to form non-conductive depletion region as the channel of transistor. Furthermore, the LV-HEMT T₁/T₂ further includes a gate G₁/G₂ formed on the p-GaN layer 104, and a source S₁/S₂ and a drain D₁/D₂ formed on the GaN substrate 100 and AlGaN layer 102 respectively at two sides of the p-GaN layer 104. In the embodiment, the width of gate G₁/G₂ (in the direction perpendicular to page) is preferably greater than 1000 μm. In addition, the gate-to-drain length LGD Of HEMT may have different dimension correspondingly for different operating voltages. For example, with respect to high-voltage (HV) device, the length LGD is preferably between 15 μm-20 μm. With respect to moderate voltage device, the length LGD is preferably between 1.8 μm-5 μm. With respect to low-voltage (LVV) device, the length L_{GD} is preferably between 1 μm-1.8 μm. Likewise, the material of gate G₁/G₂, source S₁/S₂ and drain D₁/D₂ may include refractory metal or conductive layer of relevant compound, like Ti, TiN, TiW and W, or may include Ni, Au, Cu or the alloy thereof. In the embodiment of present invention, take the first LV-HEMT T₁ as an example, when positive voltage surge enters the chip from I/O terminal, the first gate G₁ is asserted upward to an active level and conducted, then when the second LV-HEMT T₂ coupling with the first source S₁ is also turned on, the first conductive path from the I/O terminal to first reference voltage V_{R1} through the first LV-HEMT T₁ and second LV-HEMT T₂ is therefore established to release ESD surge.

According to the aforementioned embodiments, it may be understood that one major feature of the present invention is that all components in the ESD protection circuit may be GaN-based devices and/or may be compatible with the process of GaN-based devices, including resistors, capacitors, lateral field effect rectifiers or HEMTs. These devices may be manufactured on the same GaN substrate and integrally formed in the same process. For example, the main resistor R and first/second 2 DEG resistors R₁/R₂, the first/second triggers C₁/C₂ or FER₁/FER₂, and the power HEMT T and first/second LV-HEMTs T₁/T₂ may share the same GaN substrate 100 and the same AlGaN layer 102. Furthermore, the first/second triggers C₁/C₂ or FER₁/FER₂, and the power HEMT T and first/second LV-HEMTs T₁/T₂ may further share the same p-GaN layer 104. This scheme is beneficial for the circuit design and process integration of power HEMT device, reducing necessary cost and steps, which is the advantage of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ESD protection circuit using GaN devices, comprising:
a power HEMT with a gate, a source and a drain, said source and said drain are coupled respectively to a first reference voltage and a second reference voltage; and
an ESD block, comprising:
a first sub-block, comprising:
a first 2 DEG resistor with one terminal coupled to said gate;
a first trigger with one terminal coupled to another terminal of said first 2 DEG resistor and with another terminal coupled to said first reference voltage; and
a first LV-HEMT with a first gate, a first source and a first drain, said first gate is coupled to said another terminal of said first 2 DEG resistor and said terminal of said first trigger, and said first drain is coupled to said gate; and
a second sub-block, comprising:
a second trigger with one terminal coupled to said gate;
a second 2 DEG resistor with one terminal coupled to another end of said second trigger and with another terminal coupled to said first reference voltage; and
a second LV-HEMT with a second gate, a second source and a second drain, said second gate is coupled to said another terminal of said second trigger and said terminal of said second 2 DEG resistor, and said second drain is coupled to said first source of said fist LV-HEMT, and said second source is coupled to said first reference voltage.

2. The ESD protection circuit using GaN devices of claim 1, wherein said first trigger is a GaN capacitor, comprising:
a GaN substrate;
an AlGaN layer on said GaN substrate;
a p-GaN layer on said AlGaN layer and coupled with an anode; and
a cathode on said GaN substrate and said AlGaN layer at one side of said p-GaN layer.

3. The ESD protection circuit using GaN devices of claim 1, wherein said second trigger is a GaN capacitor, comprising:
a GaN substrate;
an AlGaN layer on said GaN substrate;
a p-GaN layer on said AlGaN layer and coupled with an anode; and
a cathode on said GaN substrate and said AlGaN layer at one side of said p-GaN layer.

4. The ESD protection circuit using GaN devices of claim 1, wherein said first trigger is a metal-insulator-metal capacitor, comprising:
a GaN substrate;
an ion implant isolation layer on said GaN substrate;
a passivation layer on said ion implant isolation layer;
an anode metal layer in said passivation layer; and
a cathode metal layer on said passivation layer.

5. The ESD protection circuit using GaN devices of claim 1, wherein said second trigger is a metal-insulator-metal capacitor, comprising:
a GaN substrate;
an ion implant isolation layer on said GaN substrate;
a passivation layer on said ion implant isolation layer;
an anode metal layer in said passivation layer; and
a cathode metal layer on said passivation layer.

6. The ESD protection circuit using GaN devices of claim 1, wherein said first trigger comprises at least one lateral field effect rectifier in serial connection, and each said lateral field effect rectifier comprises:
a GaN substrate;
an AlGaN layer on said GaN substrate;
a p-GaN layer on said AlGaN layer and coupled with a first anode; and
a cathode and a second anode on said GaN substrate and said AlGaN layer respectively at two sides of said p-GaN layer, wherein said first anode is coupled to said second anode.

7. The ESD protection circuit using GaN devices of claim 1, wherein said second trigger comprises at least one lateral field effect rectifier in serial connection, and each said lateral field effect rectifier comprises:
a GaN substrate;
an AlGaN layer on said GaN substrate;
a p-GaN layer on said AlGaN layer and coupled with a first anode; and
a cathode and a second anode on said GaN substrate and said AlGaN layer respectively at two sides of said p-GaN layer, wherein said first anode is coupled to said second anode.

8. The ESD protection circuit using GaN devices of claim 1, further comprising a main 2 DEG resistor with one terminal coupled to said gate and another terminal coupled to said terminal of said first 2 DEG resistor, said terminal of said second trigger and said first drain.

9. The ESD protection circuit using GaN devices of claim 8, wherein said main 2 DEG resistor comprises:
a GaN substrate;
an AlGaN layer on said GaN substrate; and
a high-voltage terminal and a low-voltage terminal on said GaN substrate and said AlGaN layer.

10. The ESD protection circuit using GaN devices of claim 1, wherein said first 2 DEG resistor comprises:
a GaN substrate;
an AlGaN layer on said GaN substrate; and
a high-voltage terminal and a low-voltage terminal on said GaN substrate and said AlGaN layer.

11. The ESD protection circuit using GaN devices of claim 1, wherein said second 2 DEG resistor comprises:
a GaN substrate;
an AlGaN layer on said GaN substrate; and
a high-voltage terminal and a low-voltage terminal on said GaN substrate and said AlGaN layer.

12. The ESD protection circuit using GaN devices of claim 1, wherein said first LV-HEMT comprises:
a GaN substrate;
an AlGaN layer on said GaN substrate;
a p-GaN layer on said AlGaN layer and coupled with said first gate; and
said first source and said first drain on said GaN substrate and said AlGaN layer respectively at two sides of said p-GaN layer.

13. The ESD protection circuit using GaN devices of claim 1, wherein said second LV-HEMT comprises:
a GaN substrate;
an AlGaN layer on said GaN substrate;
a p-GaN layer on said AlGaN layer and coupled with said second gate; and
said second source and said second drain on said GaN substrate and said AlGaN layer respectively at two sides of said p-GaN layer.

14. The ESD protection circuit using GaN devices of claim 1, wherein said first 2 DEG resistor, said first trigger, said first LV-HEMT, said second 2 DEG resistor, said second trigger and said second LV-HEMT share the same said GaN substrate and the same said AlGaN layer.

15. The ESD protection circuit using GaN devices of claim 1, wherein said first trigger, said second trigger, said first LV-HEMT and said second LV-HEMT share the same said p-GaN layer.

16. The ESD protection circuit using GaN devices of claim 1, wherein said first trigger has a threshold voltage, and when a voltage of said terminal of said first trigger is greater than a voltage of said another terminal of said first trigger and a voltage difference therebetween exceeds said threshold voltage of said first trigger, said first trigger conducts; and said first LV-HEMT has a threshold voltage, and when a voltage of said first gate of said first LV-HEMT is greater than a voltage of said first source and a voltage of said first drain and when a voltage difference therebetween exceeds said threshold voltage of said first LV-HEMT, said first LV-HEMT conducts, and said threshold voltage of said first trigger is greater than said threshold voltage of said first LV-HEMT.

17. The ESD protection circuit using GaN devices of claim 1, wherein said second trigger has a threshold voltage, and when a voltage of said terminal of said second trigger is greater than a voltage of said another terminal of said second trigger and a voltage difference therebetween exceeds said threshold voltage of said second trigger, said second trigger conducts; and said second LV-HEMT has a threshold voltage, and when a voltage of said second gate of said second LV-HEMT is greater than a voltage of said second source and a voltage of said second drain and when a voltage difference therebetween exceeds said threshold voltage of said second LV-HEMT, said second LV-HEMT conducts, and said threshold voltage of said second trigger is greater than said threshold voltage of said second LV-HEMT.
